(19) United States
(12) Patent Application Publication
(10) Pub. No.: US 2009/0221146 A1
(43) Pub. Date: Sep. 3, 2009

(54) Nonvolatile memory device and manufacturing method for the same

(75) Inventors: Akiyoshi Seko, Tokyo (JP); Natsuki Sato, Tokyo (JP); Isamu Asano, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/379,772

(22) Filed: Feb. 27, 2009

(30) Foreign Application Priority Data
Feb. 29, 2008 (JP) 2008-049751

(51) Int. Cl. H01L 21/306

(52) U.S. Cl. 438/694; 438/720; 257/E21.215

(57) ABSTRACT

The object of the present invention is to provide a manufacturing method for a nonvolatile memory device including a variable resistance having a constricted shape. The nonvolatile memory device of the present invention has a storage section composed of two electrodes and a variable resistance sandwiched between the electrodes. The variable resistance is formed to a constricted shape between the electrodes.

### BACKGROUND OF THE INVENTION

1Field of the Invention

The present invention relates to a nonvolatile memory device and a manufacturing method for the same.

2. Description of the Related Art

An improvement in the performance of a solid-state memory device formed by using a semiconductor integrated circuit technology is essential for the current advanced information-oriented society, together with an improvement in the computing power of an information processing unit (Micro Processing Unit: MPU) in particular, the amount of memory required by a computer or a piece of electronic equipment has been increasing. Since a solid-state memory device does not have a physical drive portion, unlike magnetic and magneto-optical storage devices such as a hard disk and a laser disk, it has high mechanical strength and can be further integrated by using semiconductor manufacturing technology. Accordingly, solid-state memory devices are used not only as temporary storages (caches) and main storages (main memories) of computers and servers but also as external storages (storage memories) of many mobile devices and household electrical appliances and this has now become a multi billion dollar market.

Such solid-state memory devices are roughly divided into three types: SRAMs (Static Random Access Memories), DRAMs (Dynamic Random Access Memories), and EEPROMs (Electrically Erasable and Programmable Read Only Memories) including flash memory devices. SRAMs operate at the highest speed among these memory devices. However, since SRAMs cannot hold information when the power supply is stopped, and the number of transistors required per bit is large, they are not suitable for an increase in capacity. SRAMs are thus mainly used as caches in MPUs. Although DRAMs require refresh operations and are inferior to SRAMs in operating speed, they are easy to integrate, and the unit price per bit is low. DRAMs are thus mainly used as main memories of computing devices and household electrical appliances. EEPROMs are nonvolatile memory devices capable of holding information even when the power supply is disrupted. Since EEPROMs are lower in the rate at which information is written/erased than the above described memory devices and require relatively large power, they are thus mainly used as storage memories.

Along with the recent rapid growth of the mobile device market, development of DRAM-compatible solid-state memory devices capable of higher-speed, lower-power operation and nonvolatile solid-state memory devices with both features of DRAMs and those of EEPROMs are expected. Attempts have been made to develop ReRAMs (Resistive Random Access Memories) using variable resistances and FeRAMs (Ferroelectric RAMs) using ferroelectrics as such next-generation solid-state memory devices. One of the major candidates for a nonvolatile memory device capable of high-speed, low-power operation is a phase change memory device (phase change random access memory: PRAM). Since a phase change memory device has a storage information writing speed as high as about 50 ns and has a simple device configuration, it has the advantage of being easy to further integrate.

A phase change memory device is configured such that a phase change material is sandwiched between two electrodes and is a nonvolatile memory device for selectively operating the phase change material by using active elements connected in series in a circuit (e.g., MOS (Metal-Oxide-Semiconductor) transistors, junction diodes, bipolar transistors, or Schottky barrier diodes). FIG. 1 shows a schematic sectional view of a general vertical phase change memory device, and FIG. 2 shows a schematic sectional view of a vertical phase change memory cell in which general select MOS transistors are arranged. The vertical phase change memory device is configured such that two electrodes 1 and 3 which contact phase change material 2 are vertically arranged with respect to material 2. FIG. 3 shows the circuit configuration of one cell corresponding to FIG. 2. A memory cell array is composed of cells arranged in a lattice, each of which is a combination of a phase change memory-element serving as storage section 16 and select active elements (MOS transistors 9 in FIGS. 2 and 3) for controlling a current to storage section 16. Like a DRAM cell, a general cell includes two MOS transistors 9 sharing one diffusion layer 11, with lower electrode 1 being formed on a cell contact connected to an unshared diffusion layer through storage contact 6. Shared diffusion layer 11 is connected to ground wiring 14 through a cell contact, and a current to lower electrode 1 is controlled by gate electrode 12 serving as word line 15. Upper electrode 3 of the storage section is connected to a bit line through bit contact 7. The structure is characterized not only in that it allows easy further integration but also in that since it is similar in configuration to a DRAM, DRAM cell integration technology can be applied. In some cases, it is possible to form a memory cell with no select active element by devising the configuration of a circuit around the memory cell and that of the memory cell.

Data storage and erasure of a phase change memory device are performed by causing a phase change material to transit from one of two or more solid-phase states such as a (poly-)crystalline state and an amorphous state to another by thermal energy. A transition between the crystalline state and the amorphous state is recognized as a change in resistance value by connecting the phase change material to a circuit through electrodes. Application of thermal energy to the phase change material is performed by applying an electrical pulse (voltage or current pulse) across the electrodes and Joule-heating the phase change material itself. For example, if an electrical pulse with a high current is applied to phase change material in a crystalline state for a short period of time at this time, the phase change material will be heated to a high temperature near its melting point and then rapidly cooled, and it will turn into a amorphous state (hereinafter, this state will be referred to as a reset state). The operation is generally called a reset operation. If an electrical pulse with a current lower than that for a reset operation is applied to the phase change material in the reset state for a relatively long period of time, the temperature of the phase change material will rise to its crystallization temperature, and the phase change material will turn into a crystalline state (hereinafter, this state will be referred to as a set state). The operation is called a set operation in contrast to the term “reset operation.” Element resistances at the time of applying a low electric field in these states are generally called a reset resistance and a set resistance, respectively.

Since a phase change memory device is activated by a select active element, information rewriting needs to be performed within the drive current capacity of the select active element. In a phase change memory device fabricated using the most advanced lithography technology, it is difficult to set the cell integration degree to about that for a DRAM and to keep the value of a current necessary for a reset operation within the drive current capacity of the select active element.

Reduction (scaling down) of a phase change region of a phase change material is useful for low-power (low-current) operation of a vertical phase change memory device. In order to, e.g., perform a reset operation on the phase change material in the set state and recognize a state transition of the phase change material as a change in resistance value, for example it is desirable that a phase change region (a region having undergone a phase change) cover up a lower (or upper) electrode or that all current paths through the phase change material pass through the phase change region without exception. A phase change region here refers to a region where a phase change actually occurs, and there is no need for the all of the formed phase change material to serve as a phase change region.

In the phase change memory device as in FIG. 1, phase change region 5 is formed in the vicinity of an interface with lower electrode 1 where the current density at the time that information is written is the highest. Accordingly, if the contact area between the electrode and phase change material 2 is reduced, the region that will undergo a phase change can be reduced. This provides effective means for reducing power consumption at the time of information rewriting.

However, if the electrodes are reduced, since the contact resistance between the electrode and phase change material 2 may increase, it is necessary to use electrode material having relatively low resistivity. Since material having low resistivity also has low thermal resistivity, if a phase change occurs in the vicinity of the electrode, heat will be radiated from the electrode, and the heating efficiency of the phase change material will decrease.

A ReRAM is a nonvolatile memory device which utilizes the fact that application of a voltage pulse causes resistance-variable material to perform resistive switching. ReRAMs include all materials that cause resistive switching according to a change of resistance due to a phase change as in a phase change memory device. The device configuration of a ReRAM is similar to that of a phase change memory device and is configured such that two electrodes are brought into contact with a resistance-variable material.

Storage and erasure of data are performed by applying an electric pulse, as in a phase change memory device. Writing information for a transition into a high-resistance state is called resetting, and writing information for a transition into a low-resistance state is called setting. A metal oxide is often used as a resistance-variable material. It is necessary for most ReRAMs to first perform an initialization operation of applying a high electric field which is called forming in memory device actuation, in addition to an information writing operation.

Japanese Patent Laid-Open No. 2007-180474 discloses that since a resistance value of a ReRAM in the set state is lower than a parasitic resistance on a bit line, a sufficient voltage can not be applied to a resistance-variable material in a memory cell with a general parallel-plate structure in which an electrode, the resistance-variable material, and an electrode are vertically arranged in this order. Japanese Patent Laid-Open No. 2007-180474 also discloses that if the contact area between each electrode and the resistance-variable material is reduced, the interface resistance increases, and, therefore, a sufficient voltage is not applied to the resistance-variable material itself.

Methods for reducing power (current) necessary for information rewriting by covering a resistance change region of a variable resistance with insulating material are disclosed as related art in Japanese Patent Laid-Open No. 2006-210882 and National Publication of International Patent Application No. 2006-510219.

In semiconductor memory devices using a variable resistance, including a phase change memory device, a reduction of power consumption (in particular, current consumption) at the time of information rewriting is an essential issue for practical mass production. In order to vary the resistivity of a variable resistance and store information in such a memory device, it is generally necessary to apply a high electric field or a high-density current to the variable resistance. If a resistance change region of the variable resistance needed for the element to store information is reduced (scaled down), and if the amount of applied energy that is needed to cause a change in resistance can be reduced, power consumption (current consumption) can be reduced.

The simplest method for scaling down a resistance change region is a method for reducing the size of either one of two electrodes connected to a variable resistance or the contact area of the electrode with the variable resistance in order to vary the resistance of the variable resistance in the vicinity of the electrode interface. Although this method is relatively easy, an increase in interface resistance due to a reduction in the size of the may make an element resistance unduly large. Additionally, if the size of either one of the two electrodes is extremely reduced, a change in device characteristic may occur due to a nonuniform electric field in the vicinity of the interface.

A phase change memory device using the phase change material suffers from the problem that if a resistance value is controlled by causing a phase change in the vicinity of the interface between the electrode and the phase change material, heat radiation through the electrodes will reduce heating efficiency and increase power consumption.

As a currently available solution to the above-described problem, Japanese Patent Laid-Open No. 2007-180474 discloses a semiconductor memory device in which the resistance change region is made smaller in cross-sectional area than the contact interface between the electrode and a variable resistance and which has a locally constricted structure at the variable resistance. The invention as described in Japanese Patent Laid-Open No. 2007-180474 discloses a structure in which the minimum cross-sectional area of a variable resistance is smaller than the cross-sectional area of the contact region with the electrode. However, a specific method for forming a memory element with such a constricted structure is not mentioned, and a method using simple etching may cause a variable resistance structure to collapse at the time of forming a constricted structure.

The methods for reducing power (current) necessary for information rewriting by covering the resistance change region of a variable resistance with an insulating material disclosed in Japanese Patent Laid-Open No. 2006-210882 and National Publication of International Patent Application No. 2006-510219 are basically no different in that the resistance change is produced in the vicinity of the electrode interface.

### SUMMARY OF THE INVENTION

Therefore, the object of the present invention is to provide a nonvolatile memory device including a variable resistance with a constricted shape and a manufacturing method for the same.

According to the present invention, a manufacturing method for a nonvolatile memory is provided.

[1] A method of manufacturing a semiconductor memory device, comprising:

forming a lower electrode, a variable resistance section, and an upper electrode above a main surface of a semiconductor substrate;

etching the lower electrode, the variable resistance section and the upper electrode by an anisotropic etching; and

etching the variable resistance section by an isotropic etching.

[2] The method according to [1], wherein the etching the variable resistance section includes changing a shape of the variable resistance section to be constricted shape.

[3] The method according to [1], wherein the etching the variable resistance section includes etching the variable resistance section from a first direction parallel to the main surface.

[4] The method according to [3], wherein the forming the lower electrode, the variable resistance section and the upper electrode includes depositing the lower electrode, the variable resistance section and the upper electrode along a second direction perpendicular to the first direction.

[5] The method according to [1], wherein the isotropic etching is an isotropic dry etching.

[6]. The method according to [5], wherein the isotropic dry etching is performed in a condition of being supplied etching gas and power to excite and ionize the etching gas, and the power is in a range of 100 to 1000 W.

[7] The method according to [5], wherein the isotropic dry etching is performed in a condition of being supplied etching gas and carrier gas and an amount of the carrier gas to that of the etching gas is in a range of 5 times to 15 times.

[8] The method according to [1], wherein the etching the variable resistance section includes forming a first portion in the variable resistance section, and the first portion has a smaller width than a width of a second portion at which the variable resistance section contacts with the lower electrode.

[9] The method according to [1], further comprising forming a support insulating layer contacting with the variable resistance before the etching the variable resistance section by an isotropic etching.

[10] The method according to [9], wherein the etching the variable resistance section includes etching the variable resistance section from an opposite side of the support insulating layer.

[11] The method according to [9], wherein the forming the support insulating layer includes forming an opening portion through the lower electrode, the variable resistance section and the upper electrode and depositing an insulating material into the opening portion.

[12] The method according to [1], wherein the forming the lower electrode, the variable resistance section, and the upper electrode includes forming a phase change material on the lower electrode as the variable resistance section.

[13] The method according to [1], wherein the etching the variable resistance section includes etching the variable resistance from a side of the variable resistance section.

Reducing the size of a central portion of a variable resistance using isotropic dry etching makes it possible to manufacture the variable resistance having a constricted shape. In particular, the present invention is capable of forming a constricted shape without causing the variable resistance to collapse by performing isotropic dry etching while at least one surface of the variable resistance is in contact with a support insulator layer.

### BRIEF DESCRIPTION OF THE DRAWINGS

FIG. 1 is a schematic sectional view of a general vertical phase change memory device;

FIG. 2 is a schematic sectional view of a vertical phase change memory cell in which general select-MOS transistors are arranged;

FIG. 3 is a schematic circuit diagram of one cell corresponding to FIG. 2;

FIGS. 4(A) to 4(C) are a top view and schematic local sectional views after lower electrode material 1, phase change material 2, and upper electrode material 3 are deposited above contact plugs 10 and on insulator layer 4;

FIGS. 5(A) to 5(C) are a top view and schematic local sectional views after upper electrode material 3, phase change material 2, and lower electrode material 1 are patterned, following FIGS. 4(A) to 4(C);

FIGS. 6(A) to 6(C) are a top view and schematic local sectional views after support insulator layer 17 is formed in a space formed by the patterning, and the surface is planarized, following FIGS. 5(A) to 5(C);

FIGS. 7(A) to 7(C) are a top view and schematic local sectional views after upper electrode 3 is selectively thinned by etchback, following FIGS. 6(A) to 6(C);

FIGS. 8(A) to 8(C) are a top view and schematic local sectional views after sidewall 18 is formed by depositing an insulating material and performing anisotropic etching, following FIGS. 7(A) to 7(C);

FIGS. 9(A) to 9(C) are a top view and schematic local sectional views after patterning is performed on upper electrode material 3, phase change material 2, and lower electrode material 1 using sidewall 18 as a mask, following FIGS. 8(A) to 8(C);

FIGS. 10(A) to 10(C) are a top view and schematic local sectional views after upper electrode material 3, phase change material 2, and lower electrode material 1 are patterned using mask 19 indicated by dotted lines, following FIGS. 9(A) to 9(C);

FIGS. 11(A) to 11(C) are a top view and schematic local sectional views after a central portion of phase change material 2 is thinned by isotropic selective dry etching, and a constricted structure is formed, following FIGS. 10(A) to 10(C);

FIGS. 12(A) to 12(C) are a top view and schematic local sectional views after a gap formed by the etching is filled with an insulating material by the spin coat method or the like, following FIGS. 11(A) to 11(C);

FIGS. 13(A) to 13(C) are a top view and schematic local sectional views after upper electrode material 3 is exposed by planarizing the surface, following FIGS. 12(A) to 12(C);

FIGS. 14(A) to 14(C) are a top view and schematic local sectional views after bit line 8 is deposited, and patterning is performed, following FIGS. 13(A) to 13(C);

FIGS. 15(A) to 15(C) are a top view and schematic local sectional views after the phase change memory device with a structure in which the phase change material is locally reduced (constricted) is completed by depositing a protective insulating material, following FIGS. 14(A) to 14(C);

FIGS. 16(A) and 16(B) are a top view and a schematic local sectional view after lower electrode material 1, phase change material 2, and upper electrode material 3 are sequentially deposited on a substrate including ground contact 22, insulator layer 4, and contact plug 10 connected to a select active element or a piece of lower wiring at a surface;

FIGS. 17(A) and 17(B) are a top view and a schematic local sectional view after electrode materials 1 and 3 and phase change material 2 on ground contact 22 are partially removed by patterning, following FIGS. 16(A) and 16(B);

FIGS. 18(A) and 18(B) are a top view and a schematic local sectional view after thermal control insulating layer 23 is deposited, following FIGS. 17(A) and 17(B);

FIGS. 19(A) and 19(B) are a top view and a schematic local sectional view after a thin sidewall made of thermal control insulating layer 23 is formed, following FIGS. 18(A) and 18(B);

FIGS. 20(A) and 20(B) are a top view and a schematic local sectional view after heat radiating layer 24 is formed, and the surface is planarized by CMP or the like, following FIGS. 19(A) and 19(B);

FIGS. 21(A) and 21(B) are a top view and a schematic local sectional view after an insulating material is deposited, and sidewall 18 is formed in the same manner as in the first exemplary embodiment, following FIGS. 20(A) and 20(B);

FIGS. 22(A) and 22(B) are a top view and a schematic local sectional view after patterning is performed in the same manner as in the first exemplary embodiment, and a constricted structure is formed by selectively thinning a central portion of the phase change material, following FIGS. 21(A) and 21(B);

FIGS. 23(A) and 23(B) are a top view and a schematic local sectional view after an insulating material is deposited in a space formed by etching in the same manner as in the first exemplary embodiment, and planarization is performed, following FIGS. 22(A) and 22(B);

FIGS. 24(A) and 24(B) are a top view and a schematic local sectional view after making a phase change memory device capable of controlling heat characteristics by depositing an insulating film, forming a contact hole for a bit line, and depositing a contact material such as tungsten, following FIGS. 23(A) and 23(B);

FIG. 25 is a sectional view of one cell composed of phase change memory devices and select transistors located below and connected to the phase change memory devices, according to the first exemplary embodiment;

FIG. 26 is a sectional view of one cell composed of phase change memory devices and select transistors located below and connected to the phase change memory devices, according to a second exemplary embodiment; and

FIG. 27 is a schematic diagram showing an example of a data processing system including a semiconductor memory device according to the present invention.

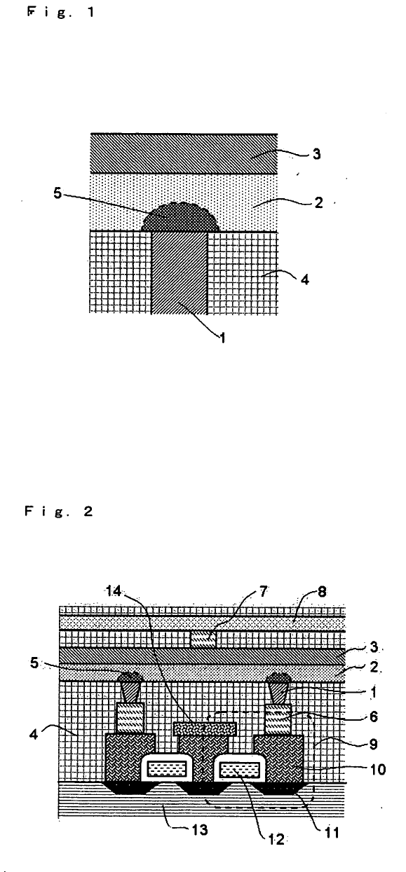

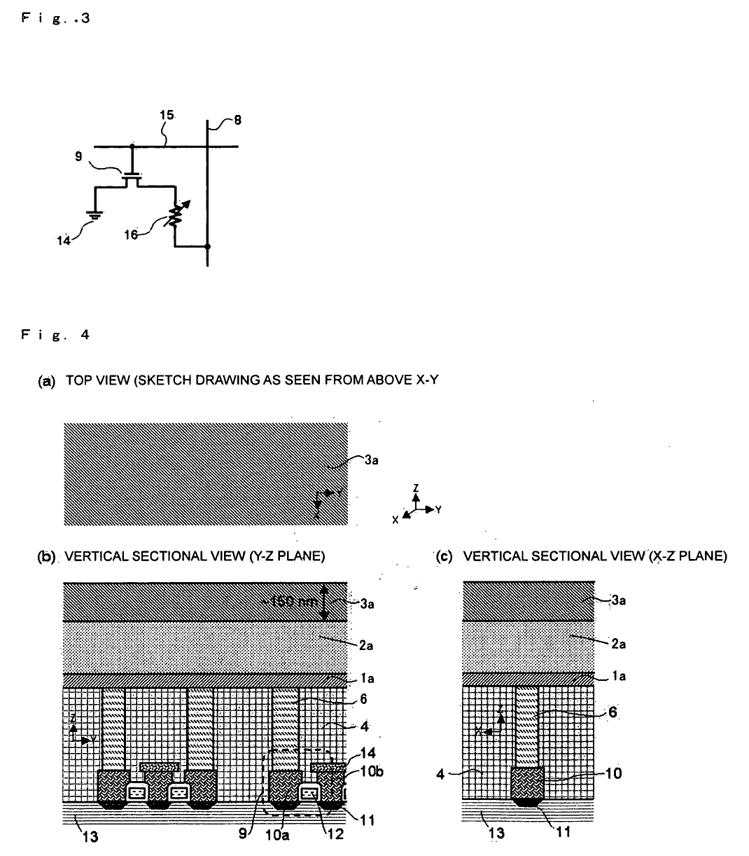

### DETAILED DESCRIPTION OF THE PREFERRED EMBODIMENTS

The present invention is a manufacturing method for a nonvolatile memory device using a variable resistance. The nonvolatile memory device has a portion at which the cross-sectional area of the variable resistance in a direction parallel to the surface of electrode is locally smaller than the contact area between each of the electrodes and the variable resistance, i.e., a variable resistance having a constricted shape is formed by using isotropic dry etching.

A size reduction by using isotropic dry etching makes it possible to manufacture a variable resistance with a constricted shape almost at the center of the variable without causing the contact area between the variable resistance and each electrode to reduce. Note that a nonvolatile memory device including a variable resistance having such a constricted shape is capable of reducing the power (current) consumption of the element while suppressing an increase in interface resistance, as described above. Since the current density and the electric field are maximum at a point where the cross-sectional area of the variable resistance is minimum, a resistance change region where a change in electric resistance occurs is formed around the point. At this time, since the volume of the resistance change region is small due to the constricted structure, the amount of power (current) necessary for rewriting of information can be reduced. Additionally, since a heat radiating source such as a metal electrode is not present around the resistance change region, it is possible to increase the heating efficiency at the time of rewriting information in the nonvolatile memory device.

When a variable resistance is formed by isotropic dry etching into a constricted shape, a support insulator layer made of an insulating material can be formed such that the support insulator layer is in contact with the variable resistance to support the variable resistance. This suppresses a collapse of the variable resistance structure.

As for the shape of a variable resistance to be manufactured by the present invention, the cross-sectional area of the thinnest region in the variable resistance is smaller than the contact area of each electrode that has the variable resistance.

Two electrodes electrically connected to a variable resistance only need to sandwich the variable resistance and are not limited to ones arranged above and below the variable resistance.

It is necessary for isotropic dry etching at the time of forming a constricted structure of a variable resistance to optimize conditions for the etching. For example, if a gas containing chlorine (Cl₂) as an etching gas and argon (Ar) as a carrier gas are used for a phase change material, the mixture ratio of the gas containing Cl₂ and Ar is set to be in the range of from 1:5 to 1:15, and the gas supply pressure is set to be in the range of from 1.0 to 4.0 Pa. Power to be supplied at the time of exciting and ionizing the gases (an AC bias to be applied to electrodes) is set to be in the range of from 100 to 1,000 W. Use of the above-described etching conditions makes it possible to make the etching rate at a central portion of a phase change material higher than that around electrodes and to form the phase change material so that it has a constricted structure.

Similarly, it is possible to control dry etching conditions for a resistance-variable material (gas species, a gas mixture ratio, a gas pressure, and power to be supplied at the time of exciting and ionizing gas (an AC bias to be applied to electrodes)) such that the etching rate at a central portion of the resistance-variable material is made higher than that around the electrodes and to form the resistance-variable material so that it has a constricted structure.

As an electrode material, a material which serves as an electrode can be used without any specific limitation. For example, any metal selected from titanium (Ti), tantalum (Ta), molybdenum (Mo), niobium (Nb), zirconium (Zr), and tungsten (W), a nitride containing the metal, a silicide compound containing the metal and the nitride, or an alloy containing the metal can be used as the material for electrodes. Components of a compound such as a nitride or silicide from which the electrode material is to be formed need not be in the stoichiometric mixture ratio. Alternatively, impurities such as carbon (C) may be added to the electrode material.

If a phase change material is adopted as the material for a variable resistance, for example, a chalcogenide material can be used as the phase change material. Chalcogen elements are elements of group VI of the periodic table and are sulfur (S), selenium (Se), and tellurium (Te). A chalcogenide material is generally a compound that is made of the chalcogen elements with any one or plural of germanium (Ge), tin (Sn), and antimony (Sb). At this time, a material that has an added element such as nitrogen (N), oxygen (O), copper (Cu), or aluminum (Al) may be used.

If a resistance-variable material is adopted as the material for a variable resistance, for example, a binary transition metal oxide such as titanium oxide (TiO₂), nickel oxide (NiO), or copper oxide (CuO) can be used as the material. Alternatively, a multicomponent oxide containing an element such as praseodymium (Pr), calcium (Ca), manganese (Mn), strontium (Sr), or zirconium (Zr) and oxygen (O) may be used.

For example, any method such as physical vapor deposition using a sputtering system or the like, chemical vapor deposition (CVD), the sol-gel method, or the spin-coat method may be used as a method for forming a film of an electrode material, a variable resistance material, and an insulating material.

In a manufacturing method according to the present invention, a support insulator layer made of an insulating material can be formed such that the support insulator layer is in contact with a variable resistance. This makes it possible to suppress a collapse of the variable resistance at the time of locally reducing the variable resistance by isotropic dry etching.

Exemplary embodiments will be described below. The following description, however, is not intended to limit the scope of the present invention.

### First Exemplary Embodiment

A manufacturing method for a nonvolatile memory device according to a first exemplary embodiment of the present invention is characterized in that

a storage section of the nonvolatile memory device is electrically connected to one of a piece of lower wiring and a select active element through at least a contact, and the method comprises following sequence:

[1] depositing a lower electrode material, a variable resistance material, and an upper electrode material on an insulating layer in which at least the contact is embedded,

[2] forming a predetermined stacked structure by etching the lower electrode material, the variable resistance material, and the upper electrode material to reach the insulating layer such that the lower electrode material, variable resistance material, and upper electrode material partially each remains at least on the contact, and

[3] forming the variable resistance into the constricted shape by subjecting the variable resistance material in the stacked structure to isotropic dry etching.

### Configuration of First Exemplary Embodiment

FIG. 25 is a sectional view of a nonvolatile memory device according to this exemplary embodiment. The nonvolatile memory device (phase change memory device) according to this exemplary embodiment is composed of phase change section 25 which functions as a storage section and select transistor 9 below phase change section 25 which is electrically connected to phase change section 25. Referring to FIG. 25, phase change section 25 according to this exemplary embodiment is composed of lower electrode 1, phase change body 2 as a variable resistance, and upper electrode 3, and bit line 8 is arranged on upper electrode 3. Select transistor 9 to be formed on semiconductor substrate 13 is formed of source/drain diffusion layer 11, gate electrode 12 serving as a word line, and the like. The diffusion layer in one side of the select transistor and lower electrode 1 of the storage section are connected to each other through cell contact 10a and storage contact 6. The diffusion layer in the other side of the select transistor is connected to a piece 14 of ground (reference potential) wiring through cell contact 10b. Phase change body 2 is sandwiched between lower electrode 1 and upper electrode 3, and upper electrode 3 is connected to bit line 8. As in a DRAM cell, two select transistors sharing one diffusion layer with each other are treated as one cell unit in the present invention, and storage section 25 is formed for each of two cell contacts 10a through storage contact 6. Such cells are separately arranged in element isolation regions (not shown) to form arrays, thereby obtaining a memory cell array.

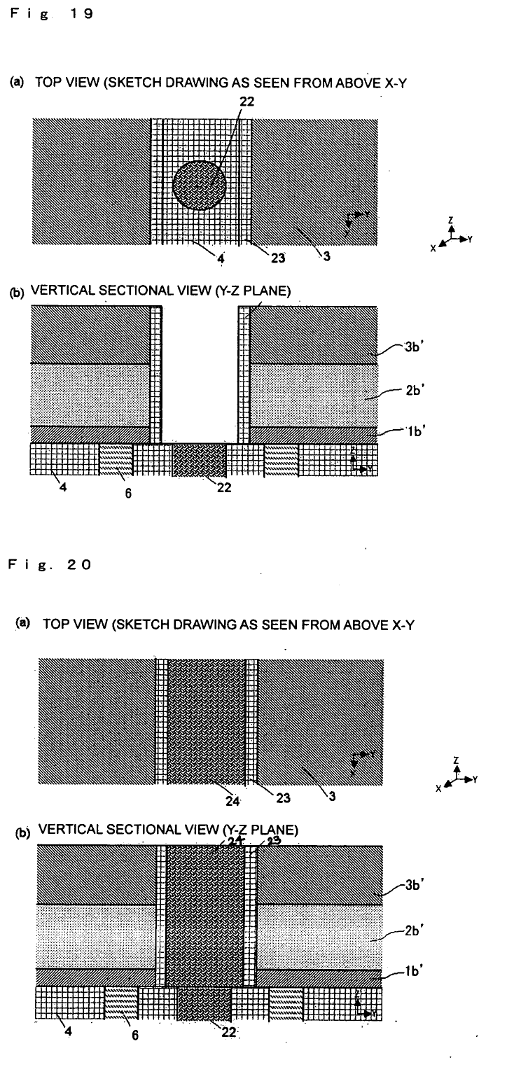

FIGS. 15(A) to 15(C) are a top view (15(A)) and sectional views (15(B) and 15(C)) of phase change body 2 of the phase change memory device according to this exemplary embodiment and its surroundings. Lower electrode 1 is provided to be in contact with storage contact 6 formed in insulator layer 4, phase change body 2 is provided on lower electrode 1, and upper electrode 3 is further provided on phase change body 2. Phase change body 2 has, at contact portions that are in contact with lower electrode 1 and upper electrode 3 (the upper end and lower end of phase change body 2), the largest cross-sectional area in a direction parallel to the electrode surfaces of the contact portions (in FIGS. 15(A) to 15(C), the horizontal direction) and has a portion whose cross-sectional area in the horizontal direction is the smallest between lower electrode 1 and upper electrode 3. At the portion that has the smallest cross-sectional area, the current density is the highest, and the amount of heat produced per unit volume is high. The portion is thus a region where a phase change mainly occurs. In order to consume less power at the time of rewriting information, the cross-sectional area at the portion with the smallest cross-sectional area is desirably about 300 to 400 nm². Since an increase in interface resistance resulting from the interface structure and the electronic state between a phase change body and each electrode increases the CR time constant in an information judgment circuit (sense amplifier circuit), it causes a reduction in the element-stored information judgment speed (read speed). In next-generation nonvolatile memory, since high-speed operation is one of the absolute musts, a reduction in interface resistance becomes a major issue. According to the above-described background, the set resistance is desirably in the range of from about 1 kΩ to 1 MΩ. In order to reduce the interface resistance and minimize the phase change region, the ratio of the cross-sectional area of the upper end or lower end of the phase change material where phase change body 2 has the largest cross-sectional area in the horizontal direction to that of the portion having the smallest cross-sectional area is desirably in the range of from 100:1 to 2:1 and is as high as possible. The element resistance also depends on the film thickness of the phase change body (the vertical height in FIGS. 15(A) to 15(C)). To prevent an increase in resistance to an extremely high value, the film thickness of the phase change body is desirably 500 nm or less. At least one surface in the vertical direction of phase change body 2 is in contact with support insulator layer 17 in order to prevent phase change body 2 from being overturned. Although a surface of phase change body 2 in contact with support insulator layer 17 is flat in this exemplary embodiment, the cross-sectional shape of the contact surface may be, e.g., arcuate for an improvement in support properties. The thickness of the support insulator layer is desirably at least about several tens of nm in order to maintain its strength.

### Description of Manufacturing Method of First Exemplary Embodiment

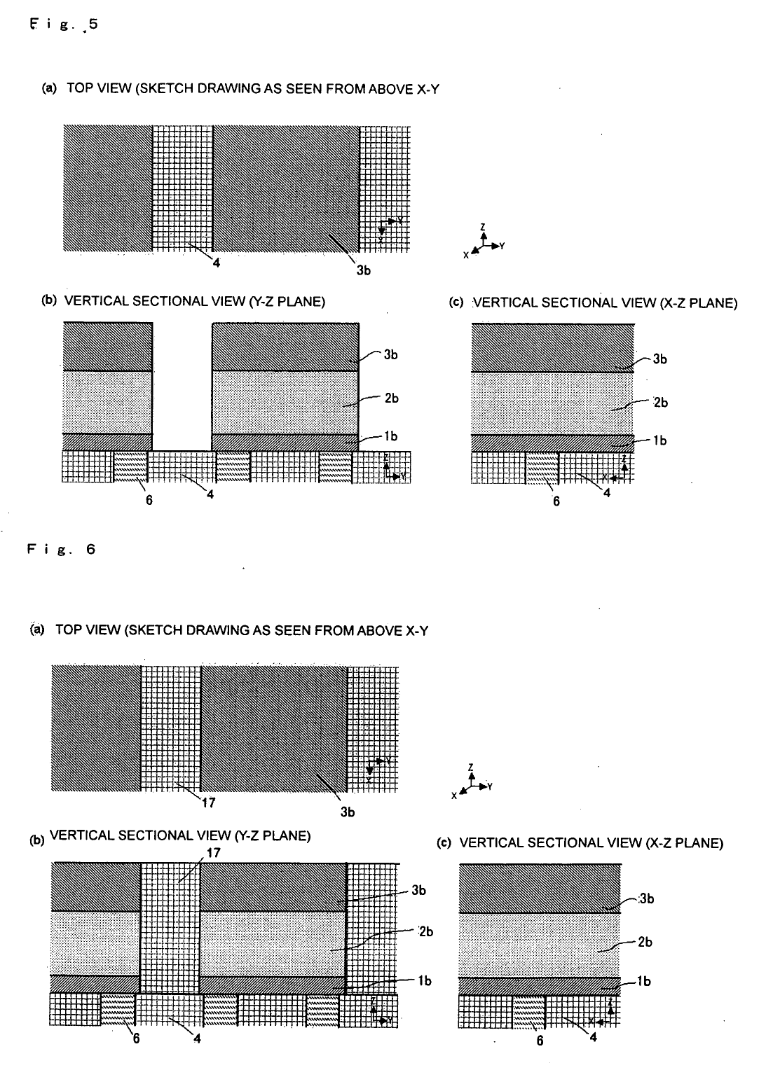

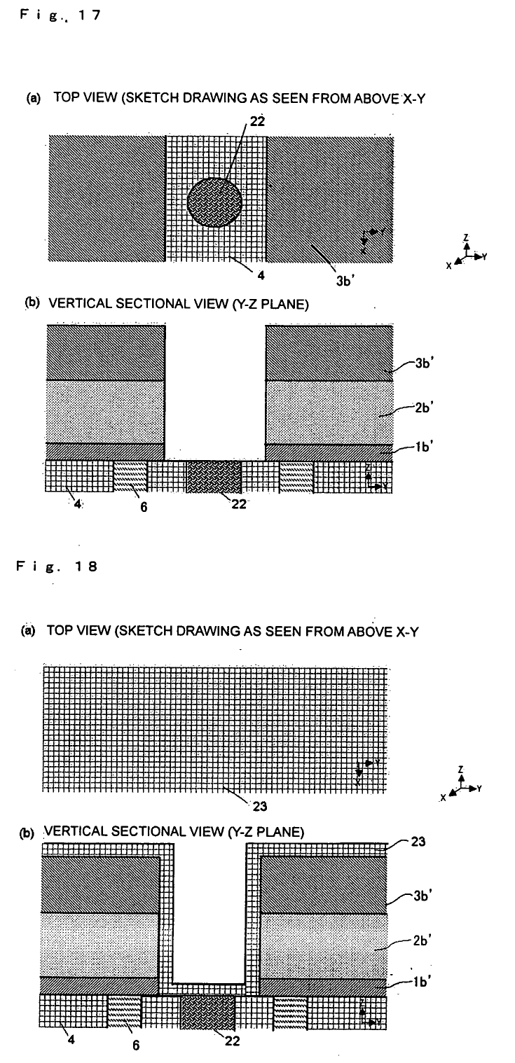

FIGS. 4(A) to 4(C) to 14(A) to 14(C) show schematic views for explaining a phase change memory device manufacturing process regarding a manufacturing method for a phase change memory device according to the first exemplary embodiment of the present invention. FIGS. 4(A) to 4(C) are a top view (4(A)) and sectional views (4(B) and 4(C)) in a process of manufacturing a vertical phase change memory device with a constricted structure made of a phase change material. The same applies to FIGS. 5(A) to 5(C) and 14(A) to 14(C). This exemplary embodiment makes it possible to form a structure by isotropic dry etching in a process of forming a variable resistance that has a locally reduced structure without causing the structure to collapse. Note that the present invention is not limited to the exemplary embodiment to be described below.

This exemplary embodiment will be described below with reference to FIGS. 4(A) to 4(C) to 14(A) to 14(C). A phase change memory device formed by this exemplary embodiment is formed with a self-alignment technique. Accordingly, the variation of the size among elements is little, and characteristic variation among elements can be suppressed in a memory cell array.

First, as shown in FIGS. 4(A) to 4(C), lower electrode material 1 a made of, e.g., titanium nitride, phase change body material 2a made of, e.g., a chalcogenide material, and upper electrode material 3a made of, e.g., titanium nitride like the lower electrode are sequentially deposited on storage contact 6 connected to a select transistor or to a piece of lower wiring manufactured on a substrate by the same manufacturing method as a conventional one. Here, the film thickness of lower electrode material 1a is about 100 nm, and the film thickness of phase change body material 2a is about 200 nm. The film thickness of upper electrode material 3a is set to a relative large thickness of about 150 nm taking into consideration etchback process (to be described later).

As shown in FIGS. 5(A) to 5(C), upper electrode material 3a, phase change body material 2a, and lower electrode material 1a are patterned. As shown-in FIGS. 6(A) to 6(C), support insulator layer material 17a made of an insulating material such as silicon dioxide (SiO₂) is deposited in a first opening formed by the patterning. Planarization of the surface is performed by CMP or the like, and support insulator layer 17 having a width of about 100 nm is formed. The insulating material is not limited to an SiO₂ film, and any suitable insulating film such as an SiN film, a polyimide film, or an SiOF film may be used. The deposition of the insulating material can be performed by any suitable deposition technique such as pulsed laser deposition, RF sputtering, e-beam evaporation, thermal evaporation, organic metal deposition, spin-on deposition, or organic metal CVD. The same applies to the exemplary embodiments below. The planarization technique is not limited to CMP. Any suitable planarization technique such as spin-on or a combination of spin-on and etchback may be used instead.

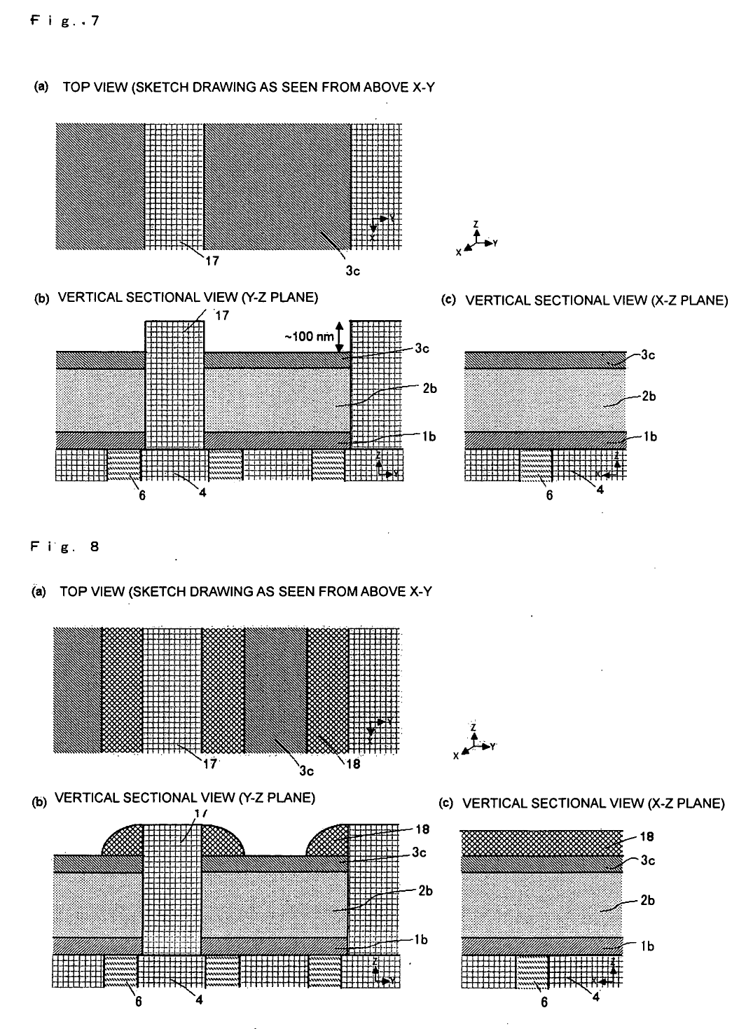

As shown in FIGS. 7(A) to 7(C), upper electrode material 3b is thinned by selectively etching the upper electrode material (the upper electrode material after thinning will be referred to as upper electrode material 3c), thereby causing an upper portion of support insulator layer 17 to protrude. It is preferable to make a difference of about 100 nm in grade level between support insulator layer 17 and upper electrode material 3c. As shown in FIGS. 8(A) to 8(C), an insulating material such as silicon nitride (SiN) is deposited, and anisotropy etching is performed, thereby forming sidewall 18 made of the insulating material on upper electrode material 3c and on each side of support insulator layer 17. Sidewall 18 is used as a mask for later etching of the electrodes and the phase change material (variable resistance material). Here, the interval between sidewalls 18 on upper electrode material 3c is about 150 nm.

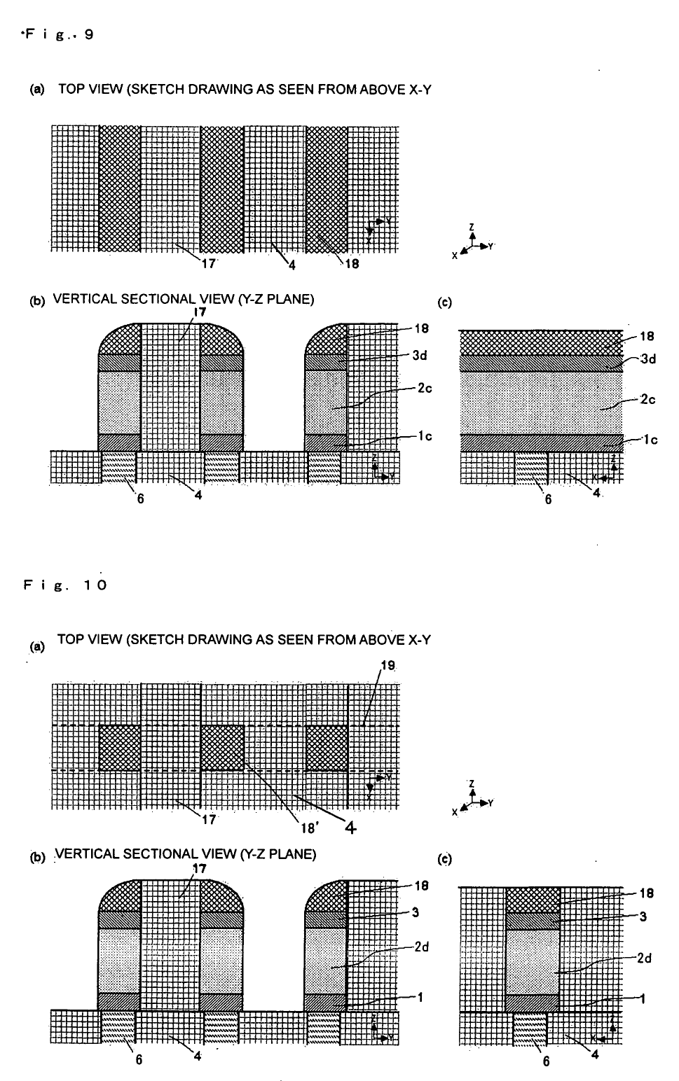

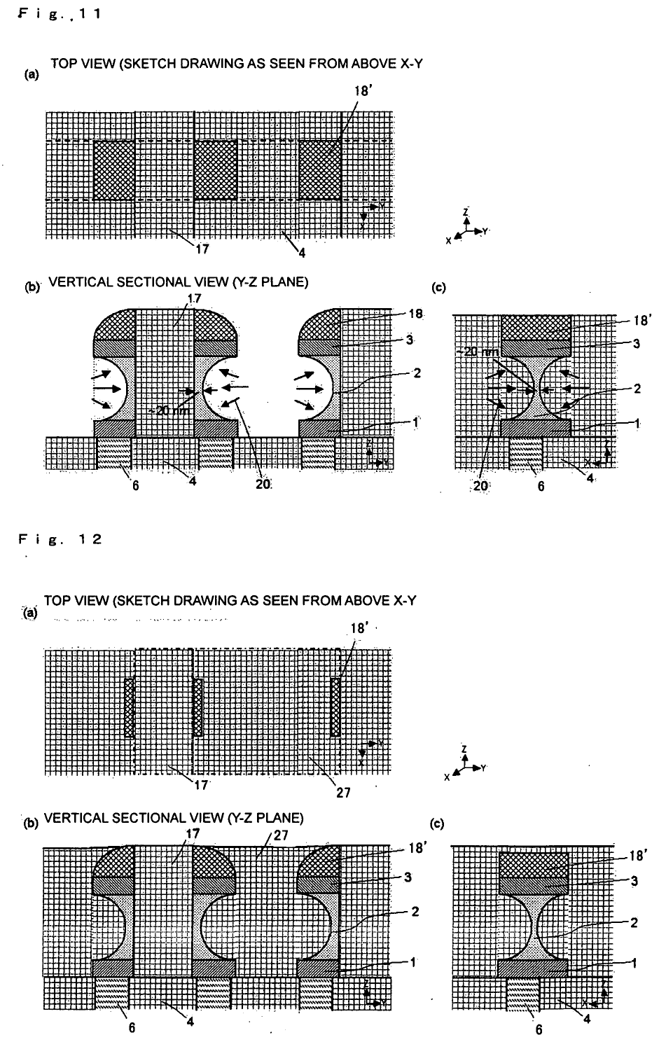

As shown in FIGS. 9(A) to 9(C), anisotropic etching, e.g., dry etching is performed on upper electrode material 3c, phase change body material 2b, and lower electrode 1b using sidewall 18 as a mask(a first stacked structure). Similarly, as shown in FIGS. 10(A) to 10(C), sidewall 18 is reduced using mask 19 indicated by dotted lines, thereby forming second mask 18′. Upper electrode 3d, phase change material 2c, and lower electrode 1c are patterned using second mask 18′. According to the two-step etching of the electrodes and phase change material, the electrodes and phase change material are shaped into a small column (a second stacked structure). At the time of these etching operations, the raw materials for etching gas and etching conditions are selected such that the etching selectivity of the side wall and support insulator layer with respect to the electrode metal and phase change material is sufficiently high.

As shown in FIGS. 11(A) to 11(C), a central portion of phase change body material 2d is locally thinned by isotropic selective dry etching, and a locally constricted structure is formed, thereby forming phase change body 2. As for isotropic dry etching, a reactant gas pressure, a mixture ratio, and the amount of plasma power are adjusted such that the etching rate is high at the central portion of phase change body material 2d while the etching rate is low at a portion around each electrode. More specifically, if Ge₂Sb₂Te₅ is used as the phase change material, a gas containing chlorine (Cl) and argon (Ar) are respectively used as the etching gas and a carrier gas, the mixture ratio of the gas containing Cl and Ar is set to be in the range of from 1:5 to 1:15, and the gas pressure is set to be in the range of from 1.0 to 4.0 Pa. Power to be supplied (an AC bias to be applied to the electrodes) at the time of exciting and ionizing the gases is set to be in the range of from 100 to 1,000 W. The setting of the above-described conditions makes it possible to achieve an etching rate ratio among portions of the phase change material in an etching time of 10 to several hundred of seconds and to form a constricted structure. Since a phase change material generally has a high etching rate and is hard to process, it is preferable to control etching amount by increasing the proportion of inert gas such as Ar and reducing the etching rate. Since support insulator layer 17 made of the insulating material is present in close contact behind phase change body material 2d, a portion of the phase change body in close contact with support insulator layer 17 does not come into contact with the etching gas. Phase change body material 2d is supported by support insulator layer 17 and can be prevented from collapsing due to a reduction in its size. The formation of support insulator layer 17 makes it possible to suppress a reduction in the yield of memory cells caused by the collapse of the phase change material.

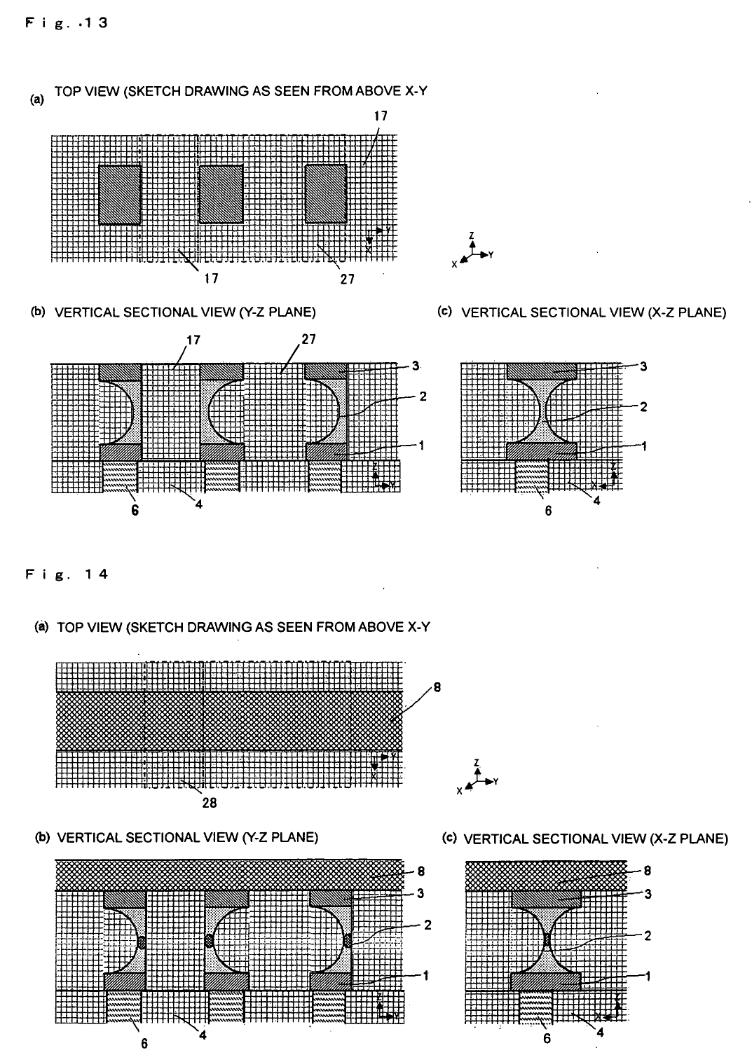

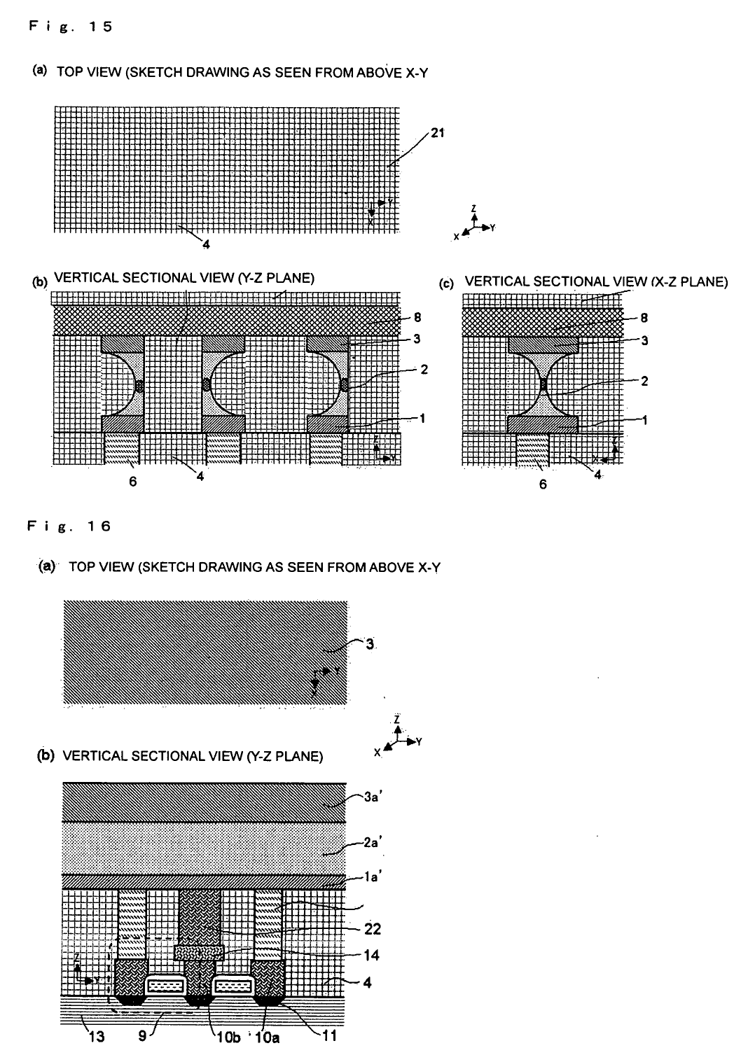

As shown in FIGS. 12(A) to 12(C), a gap formed by the etching is filled with an insulating material by the spin coat method or the like. As shown in FIGS. 13(A) to 13(C), the surface is planarized by CMP or the like, thereby exposing upper electrode 3. Although a part of upper electrode 3 is also polished at this time, the polishing is performed while making sure that exfoliation does not occur at the interface with phase change body 2. Upper electrode 3 is preferably polished to a film thickness of about 10 to 100 nm such that the resistance of upper electrode 3 is as low as possible.

As shown in FIGS. 14(A) to 14(C), bit line 8 is deposited (optionally, a bit line contact is formed) using, e.g., aluminum (Al) or copper (Cu) as a raw material by sputtering or the like, and patterning is performed. At this time, a film serving as a barrier to peripheral insulating film 28 may be formed by sputtering or the like using, e.g., titanium nitride as a raw material.

As shown in FIGS. 15(A) to 15(C), protective insulating material 21 made of, e.g., silicon oxide (SiO₂) is deposited. With this operation, a phase change memory device with a structure in which the phase change material is locally reduced (constricted) can be manufactured. The protective insulating material may be a low dielectric constant film such as a BPSG film (a silicon oxide (SiO₂) film doped with boron (B) and phosphorus (P)).

A peripheral circuit and the like are further formed using a known method. According to this operation, a semiconductor memory device including phase change memory devices as shown in FIG. 25 as a memory cell are formed.

Since the above-described structure allows a reduction in the area of each element, the present invention has an advantage for integration. In the phase change memory device, temperature profiles for a temperature rise and for a temperature fall in a region where a phase change occurs and a thermal design including heating efficiency and a cooling rate after reset pulse application are controlled by the film thicknesses of the electrodes and phase change material, the etched shape of the phase change material, and the like.

### Second Exemplary Embodiment of the Invention

### Configuration of Second Exemplary Embodiment

FIG. 26 is a sectional view of a phase change memory device according to this exemplary embodiment. The phase change memory device according to this exemplary embodiment is composed of phase change section 26 and select transistor 9 which is located below and is connected to phase change section 26. This exemplary embodiment is different from the first exemplary embodiment in the presence of heat radiating layer 24 connected to piece 14 of reference potential wiring.

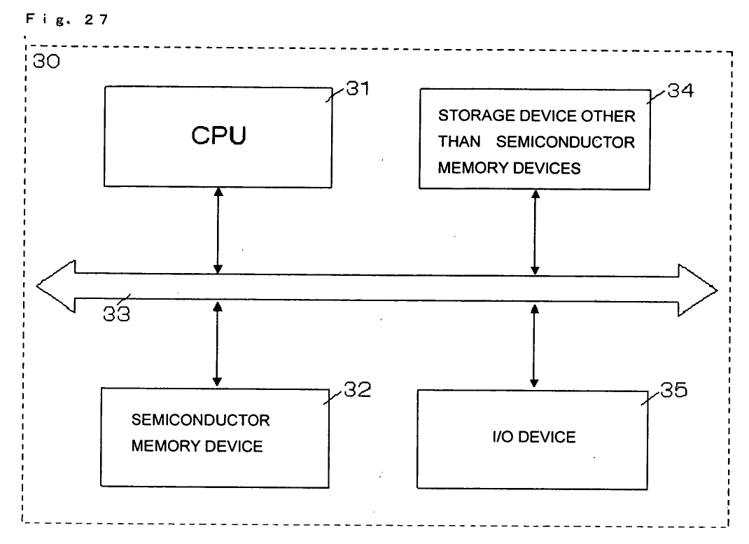

FIG. 24(B) shows a sectional view of phase change material 2 of the phase change memory device according to this exemplary embodiment and its surroundings. The phase change memory device according to this exemplary embodiment is configured to include thermal control insulating layer 23 and heat radiating layer 24 instead of support insulator layer 17 of the phase change memory device shown in FIGS. 15(A) to 15(C), and thermal control insulating layer 23 functions as the support insulator layer. Heat radiating layer 24 is configured to be in contact with ground contact 22. The width of thermal control insulating layer 23 is adjusted to be in the range of about 5 to 50 nm. Heat radiating layer 24 is preferably formed using, e.g., tungsten (W) having a high thermal conductivity to be larger in height and width than each adjacent phase change body layer.

### Description of Manufacturing Method of Second Exemplary Embodiment

FIGS. 16(A) and 16(B) to 24(A) and 24(B) show local sectional views of a phase change memory device manufacturing process regarding a manufacturing method for a vertical phase change memory device according to the second exemplary embodiment. In a phase change memory device having a constricted structure, since the electrodes and the region where a phase change occurs are not close to each other, the amount of heat radiated from the electrodes is small, and heating efficiency is high. However, the cooling rate at the time of a reset operation is low, and sufficient amorphization of the phase change material may be prevented.

In this exemplary embodiment, a ground wiring is arranged in a support insulator layer behind a phase change material, and the film thickness of the insulating material that presents between the ground wiring and a region where a phase change occurs is adjusted. Therefore, the device made in the second exemplary embodiment can easily perform a efficient thermal design than the one made in the first exemplary embodiment where a heat generation state is controlled only through adjustment of a constricted shape.

As shown in FIGS. 16(A) and 16(B), ground contact 22 is formed on piece 14 of ground wiring connected to a substrate through cell contact 10b, and contact plug 6 is formed on each cell contact 10a. Lower electrode material 1a′, phase change body material 2a′, and upper electrode material 3a′ are sequentially deposited on an upper surface of interlayer film 4 where ground contact 22 and contact plugs 6 are exposed. Here, the film thickness of lower electrode material 1a′ is about 100 nm, and that of phase change body material 2a′ is about 200 nm. The film thickness of upper electrode material 3a′ is set to a relatively large value of about 150 nm taking into consideration an etchback process (to be described later).

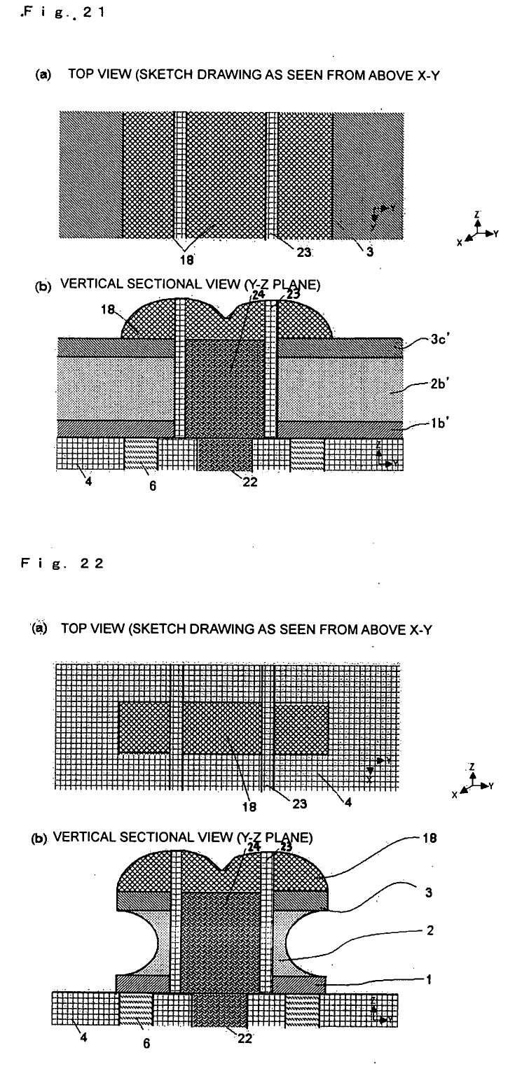

As shown in FIGS. 17(A) and 17(B), lower and upper electrode materials 1a′ and 3a′ and phase change body material 2a′ on ground contact 22 are partially removed by patterning.

As shown in FIGS. 18(A) and 18(B), insulating material 23′ such as silicon dioxide (SiO₂) is deposited on a side wall and on the bottom of a second opening formed by the removal through the patterning. The amount of heat radiated in a phase change region is controlled by adjusting the film thickness of insulating material 23′. As shown in FIGS. 19(A) and 19(B), insulating material 23′ is anisotropically etched by dry etching or the like and is shaped such that thermal control insulating layer 23 remains on the side of a second opening.

As shown in FIGS. 20(A) and 20(B), a metal material such as tungsten having excellent thermal conductivity propertis is deposited inside thermal control insulating layer 23 (in the opening), and the surface is planarized by CMP or the like, thereby forming heat radiating layer 24. Heat radiating layer 24 and upper electrode material 3b′ are etched back by dry etching or the like and are thinned, thereby exposing the upper portion of thermal control insulating layer 23. After that, as shown in FIGS. 21(A) and 21(B), sidewall 18 made of an insulating material such as silicon nitride (SiN) is formed in the same manner as in the first exemplary embodiment.

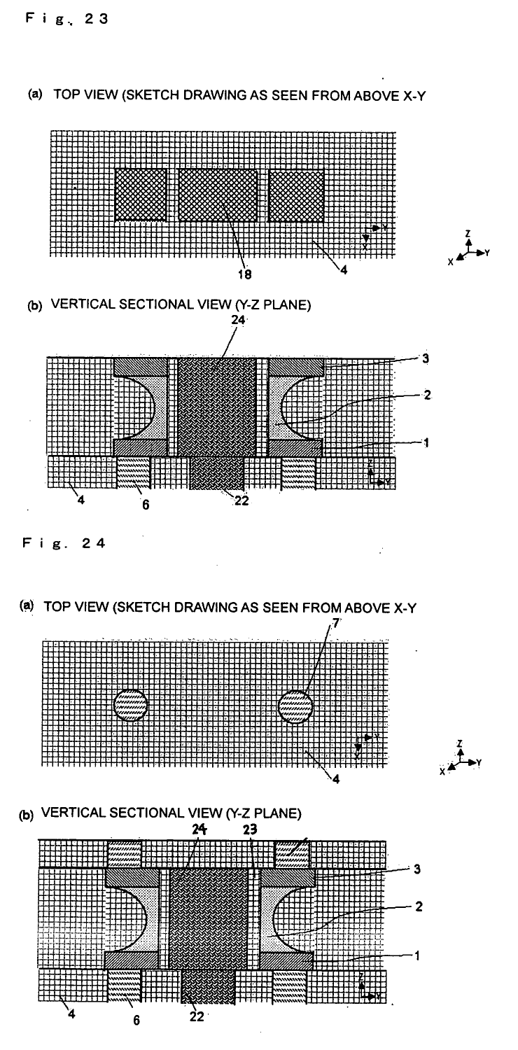

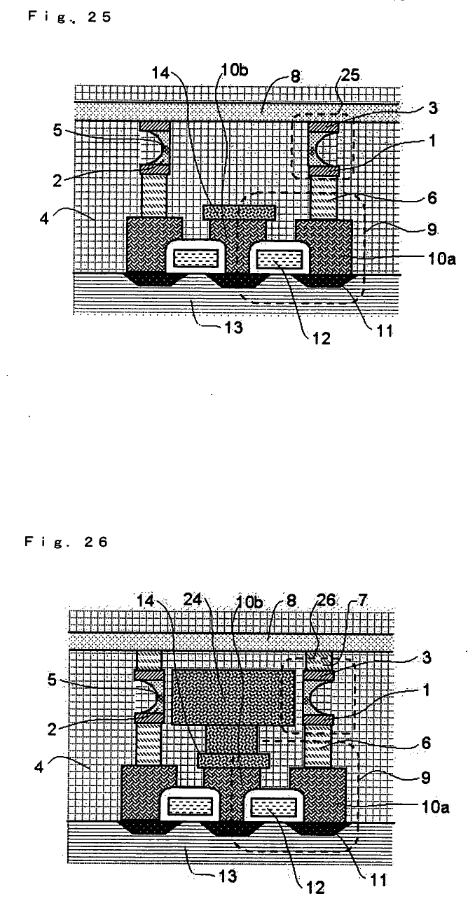

Although not shown, patterning is then performed in the same manner as in FIGS. 10(A) to 10(C) in the first exemplary embodiment. As shown in FIGS. 22(A) and 22(B), phase change body material 2b′ (FIGS. 21(A) and 21(B)) is subjected to dry etching in the same manner as in the first exemplary embodiment. According to these operations, a central portion of the phase change material is selectively thinned. As shown in FIGS. 23(A) and 23(B), the insulating material is deposited in a space formed by the etching in the same manner as in the first exemplary embodiment, and planarization is performed.

As shown in FIGS. 24(A) and 24(B), an insulating film is deposited, and a contact hole for a bit line is formed. Contact material such as tungsten (W) or aluminum (Al) is further deposited by sputtering or CVD, and the surface is finally planarized, thereby forming bit contact 7 connected to an upper electrode. In this manner, a phase change memory device capable of controlling heat characteristics according to this exemplary embodiment is completed. Bit line 8 as shown in the first exemplary embodiment is formed on bit contact 7.

By forming a peripheral circuit and the like using a known method, a semiconductor memory device including phase change memory devices as shown in FIG. 26 as a memory cell are formed.

### Third Exemplary Embodiment

### <Data Processing System>

FIG. 27 is a diagram showing a data processing system including a semiconductor memory device according to the present invention. Note that the data processing system shown in FIG. 27 is an example of a system including a semiconductor memory device, and a semiconductor memory device according to the present invention can also be widely applied to a system other than data processing systems. Although examples of a data processing system according to this exemplary embodiment include a computer system, this exemplary embodiment is not limited to this.

Referring to FIG. 27, data processing system 30 according to this exemplary embodiment includes CPU (Central Processing Unit) 31 and semiconductor memory device 32. Although CPU 31 is connected to semiconductor memory device 32 through system bus 33 in FIG. 27, CPU 31 may be connected to semiconductor memory device 32 not through system bus 33 but through a local bus. Although only one system bus 33 is shown in FIG. 27 for the sake of simplicity, system buses may be connected to one another serially or in parallel through a connector and the like as needed. In data processing system 30, storage device 34 other than semiconductor memory devices and I/O device(Input/Output device) 35 are optionally connected to system bus 33.

Examples of storage device 34 other than semiconductor memory devices include a hard disk and an MO drive, and examples of I/O device 35 include an input device such as a keyboard and an output device such as an LCD display. However, these devices are not limited to the above-described ones. I/O device 35 includes the device which operate either input or output. Semiconductor memory device 32 includes at least a variable-resistance memory device, such as a PRAM or ReRAM, which is formed by applying the present invention. Although the number of components of each type is only one in FIG. 27 for the sake of simplicity, the present invention is not limited to this. A case where the number of components of each type or any one type is more than one is also included in the present invention. For example, semiconductor memory device 32 may be formed of semiconductor memory devices, a variable-resistance memory device formed by applying the present invention and a semiconductor memory device other than variable-resistance memory devices.

Since application of the present invention makes it possible to make the power consumption of a nonvolatile memory device (variable-resistance memory device) that uses a variable resistance lower than ever before, the power consumption of data processing system 30 can be reduced. This allows application of a variable-resistance memory device to data processing system 30. As a result, it is possible to reduce power consumption of a data processing system itself and to easily form a data processing system having a nonvolatile memory device which is capable of high-speed operation and further efficient integration.

What is claimed is:

1. A method of manufacturing a semiconductor memory device, comprising:
forming a lower electrode, a variable resistance section, and an upper electrode above a main surface of a semiconductor substrate;
etching the lower electrode, the variable resistance section and the upper electrode by an anisotropic etching; and
etching the variable resistance section by an isotropic etching.

2. The method according to claim 1, wherein the etching the variable resistance section includes changing a shape of the variable resistance section to be constricted shape.

3. The method according to claim 1, wherein the etching the variable resistance section includes etching the variable resistance section from a first direction parallel to the main surface.

4. The method according to claim 3, wherein the forming the lower electrode, the variable resistance section and the upper electrode includes depositing the lower electrode, the variable resistance section and the upper electrode along a second direction perpendicular to the first direction.

5. The method according to claim 1, wherein the isotropic etching is an isotropic dry etching.

6. The method according to claim 5, wherein the isotropic dry etching is performed in a condition of being supplied etching gas and power to excite and ionize the etching gas, and the power is in a range of 100 to 1000 W.

7. The method according to claim 5, wherein the isotropic dry etching is performed in a condition of being supplied etching gas and carrier gas and an amount of the carrier gas to that of the etching gas is in a range of 5 times to 15 times.

8. The method according to claim 1, wherein the etching the variable resistance section includes forming a first portion in the variable resistance section, and the first portion has a smaller width than a width of a second portion at which the variable resistance section contacts with the lower electrode.

9. The method according to claim 1, further comprising forming a support insulating layer contacting with the variable resistance before the etching the variable resistance section by an isotropic etching.

10. The method according to claim 9, wherein the etching the variable resistance section includes etching the variable resistance section from an opposite side of the support insulating layer.

11. The method according to claim 9, wherein the forming the support insulating layer includes forming an opening portion through the lower electrode, the variable resistance section and the upper electrode and depositing an insulating material into the opening portion.

12. The method according to claim 1, wherein the forming the lower electrode, the variable resistance section, and the upper electrode includes forming a phase change material on the lower electrode as the variable resistance section.

13. The method according to claim 1, wherein the etching the variable resistance section includes etching the variable resistance from a side of the variable resistance section.
